(19) United States
(12) Patent Application Publication
(10) Pub. No.: US 2014/0000697 A1
(43) Pub. Date: Jan. 2, 2014

(54) Nanonet-Based Hematite Hetero-Nanostructures for Solar Energy Conversions and Methods of Fabricating Same

(71) Applicants: Dunwei Wang, Newton Highlands, MA (US); Yongjing Lin, Fremont, CA (US); Sa Zhou, Fremont, CA (US)

(72) Inventors: Dunwei Wang, Newton Highlands, MA (US); Yongjing Lin, Fremont, CA (US); Sa Zhou, Fremont, CA (US)

(73) Assignee: The Trustees of Boston College, Chestnut Hill, MA (US)

(21) Appl. No.: 13/979,247

(22) PCT Filed: Jan. 13, 2012
(86) PCT No.: PCT/US2012/021230

§ 371 Date: Sep. 19, 2013

Related U.S. Application Data
(60) Provisional application No. 61/432,830, filed on Jan. 14, 2011.

(51) Int. Cl. C25B 1/00; H01L 31/0352; B01J 35/00

(52) U.S. Cl. CPC C25B 1/003; B01J 35/004; H01L 31/035227
USPC 136/256; 204/291; 204/242; 427/58; 427/126.1

(57) ABSTRACT

Nanonet-based hematite hetero-nanostructures (100) for solar energy conversions and methods of fabricating same are disclosed. In an embodiment, a hetero-nanostructure (100) includes a plurality of connected and spaced-apart nanobeams (110) linked together at an about 90° angle, the plurality of nanobeams (110) including a conductive silicide core having an n-type photo-active hematite shell. In an embodiment, a device (1100) for splitting water to generate hydrogen and oxygen includes a first compartment (1120) having a two-dimensional hetero-nanostructure (1125), the hetero-nanostructure having a plurality of connected and spaced-apart nanobeams, each nanobeam substantially perpendicular to another nanobeam, the plurality of nanobeams including an n-type photoactive hematite shell having a conductive core; and a second compartment (1110) having a p-type material (1115), wherein the first compartment (1120) and the second compartment (1110) are separated by a semi-permeable membrane.

### RELATED APPLICATIONS

This application claims the benefit of and priority to U.S. Provisional Application Ser. No. 61/432,830, filed Jan. 14, 2011, the entirety of which is hereby incorporated herein by reference for the teachings therein.

### FIELD

The embodiments disclosed herein relate to hetero-nanostructures for efficient solar energy conversions, and more particularly to the fabrication of nanonet-based hematite hetero-nanostructures and methods of using same for water splitting.

### BACKGROUND

Semiconductors hold great promise for high-efficiency solar water splitting as a form of solar energy harvesting and storage. Since the first demonstration using TiO₂, a large number of materials have been studied for this application. Among them, hematite (alpha-Fe₂O₃) stands out for at least two important reasons: the bandgap of hematite (2.02.2 eV) is close to the optimum requirement for a single junction system; and hematite consists of two abundant elements and therefore is low cost and amendable to large scale implementations. Hematite has been studied for solar water splitting to generate hydrogen fuel with high theoretical conversion efficiency. Despite intense effort, however, research on using hematite for solar water splitting is progressing at a slow pace because of several challenges presented by the material's intrinsic properties. For instance, the charge diffusion distance of Fe₂O₃ is notoriously short—on the order of a few to tens of nanometers—making it extremely difficult to collect photogenerated charges. Much ongoing effort focuses on addressing this problem by doping Fe₂O₃ to increase the charge diffusion distance, or by innovating its morphology to improve charge collection, or both.

### SUMMARY

Nanonet-based hematite hetero-nanostructures for solar energy conversions and methods of fabricating same are disclosed herein. According to aspects illustrated herein, there is provided a hetero-nanostructure that includes a plurality of connected and spaced-apart nanobeams linked together at an about 90° angle, the plurality of nanobeams including a conductive silicide core having an n-type photoactive hematite shell.

According to aspects illustrated herein, there is provided a device for splitting water to generate hydrogen and oxygen that includes a first compartment having a two-dimensional hetero-nanostructure, the hetero-nanostructure having a plurality of connected and spaced-apart nanobeams, each nanobeam substantially perpendicular to another nanobeam, the plurality of nanobeams including an n-type photoactive hematite shell having a conductive core; and a second compartment having a p-type material, wherein the first compartment and the second compartment are separated by a semi-permeable membrane.

According to aspects illustrated herein, there is provided a method of fabricating a nanonet-based hematite hetero-nanostructure that includes performing chemical vapor deposition so as to fabricate a two-dimensional conductive silicide nanostructure, wherein one or more gas or liquid precursor materials carried by a first carrier gas stream react to form the nanostructure, and wherein the nanostructure has a mesh-like appearance and includes a plurality of connected and spaced-apart nanobeams linked together at an about 90° angle; annealing the nanostructure; and performing atomic layer deposition so as to deposit a conformal crystalline hematite around the nanostructure, wherein the film ranges from about 10 nm to about 40 nm, and wherein one or more gas or liquid precursor materials carried by a second carrier gas stream react to form the hematite hetero-nanostructure.

### BRIEF DESCRIPTION OF THE DRAWINGS

The presently disclosed embodiments will be further explained with reference to the attached drawings, wherein like structures are referred to by like numerals throughout the several views. The drawings shown are not necessarily to scale, with emphasis instead generally being placed upon illustrating the principles of the presently disclosed embodiments.

FIGS. 1A and 1B are electron micrographs of a 2D conductive titanium silicide (TiSi₂) nanostructure fabricated according to the methods of the presently disclosed embodiments. FIG. 1A is a scanning electron micrograph (SEM) of the 2D conductive TiSi₂ nanostructure. The nanostructure is composed of a plurality of nanonet sheets (NNs). FIG. 1B is a transmission electron micrograph (TEM) showing a single NN of the 2D conductive TiSi₂ nanostructure. Each NN has a complex structure made up of nanobeams that are linked together by single crystalline junctions with 90° angles.

FIGS. 2A, 2B and 2C show high-resolution transmission electron micrographs (HRTEMs) of a single nanobeam highlighted from FIG. 1B. The entire nanobeam is single crystalline, including the joint (FIG. 2A), the middle (FIG. 2B) and the end (FIG. 2C).

FIG. 3 shows schematic representations of an illustrative embodiment of charge transport within a Fe₂O₃/TiSi₂ hetero-nanostructure of the present disclosure. Highly conductive TiSi₂ nanonets serve as effective charge collectors. When a thin Fe₂O₃ is interfaced with a TiSi₂ nanonet, the longest distance from anywhere in the semiconductor to a location where charges can be scavenged (by H₂O oxidation in the solution) or transported (by TiSi₂) is shorter than the charge diffusion distance, permitting effective charge collection.

FIGS. 4A-4D are electron micrographs of Fe₂O₃/TiSi₂ hetero-nanostructures of the present disclosure. FIG. 4A is a SEM of the Fe₂O₃/TiSi₂ hetero-nanostructures. FIGS. 4B and 4C are low-magnification and high-magnification, respectively, TEMs revealing the uniform Fe₂O₃ coating around the TiSi₂ nanonet. FIG. 4D is a high-resolution transmission electron micrograph (HRTEM) revealing the defect-free interface between Fe₂O₃ and TiSi₂.

FIG. 5 shows I-V curves for Fe₂O₃/TiSi₂ hetero-nanostructures of the present disclosure as a function of annealing temperature. In general, samples with curves to the right are less active.

FIGS. 6A and 6B are curves showing the relationship between thickness of Fe₂O₃ and the number of atomic layer deposition (ALD) growth cycles. FIG. 6A is a curve showing photocurrent density as a function of thickness of iron oxide. FIG. 6B is a curve showing the thickness of iron oxide versus the number of ALD growth cycles.

FIG. 7 shows an X-ray Diffractrometer (XRD) plot of iron oxide on TiSi₂ with (red trace) and without (black trace) annealing. The crystal structure was identified to be hematite.

FIGS. 8A and 8B show X-ray photoelectron spectroscopy (XPS) spectra of iron oxide before and after annealing. FIG. 8A is a survey scan of XPS data with peak assignments labeled. FIG. 8B is a fine scan of the Fe 2p region. No change of oxidation state was observed before and after annealing. The binding energies for Fe 2p_{3/2} and Fe 2p_{1/2} are 710.9 and 724.3 eV, respectively, in excellent agreement with literature reports on α-Fe₂O₃.

FIGS. 9A-9D show photoelectrochemical (PEC) properties of Fe₂O₃/TiSi₂ hetero-nanostructures of the present disclosure. FIG. 9A is characteristic PEC data of the Fe₂O₃/TiSi₂ hetero-nanostructures and planar hematite film. FIG. 9B illustrates the absorption spectrum of the Fe₂O₃ film. FIG. 9C is a comparison of the external quantum efficiencies of Fe₂O₃ with and without TiSi₂ nanonets (measured at V=1.53 V vs. RHE). FIG. 9D illustrates the internal quantum efficiency of Fe₂O₃/TiSi₂ hetero-nanostructures of the present disclosure, calculated from the IPCE and the absorption spectrum.

FIGS. 10A and 10B show impedance studies revealing quantitative information on the intrinsic properties of the hetero-nanostructures of the present disclosure. FIG. 10A shows a Nyquist plot of the impedance measurements at 1.9 V (vs. reversible hydrogen electrode “RHE”). The frequency varied from 10⁵ (far left) to 1 Hz (far right). Z′ and Z″ are the real and imaginary part of the impedance, respectively. The squares represent the experimental data, while the line represents simulated data using equivalent circuits. FIG. 10B shows that flatland potential and charge carrier concentration can be extracted from the Mott-Schottky plot.

FIG. 11 shows an exemplary illustration of a device of the present disclosure for H₂O splitting.

While the above-identified drawings set forth presently disclosed embodiments, other embodiments are also contemplated, as noted in the discussion. This disclosure presents illustrative embodiments by way of representation and not limitation. Numerous other modifications and embodiments can be devised by those skilled in the art which fall within the scope and spirit of the principles of the presently disclosed embodiments.

### DETAILED DESCRIPTION

Research on using hematite (Fe₂O₃) to absorb solar light and split water is moving at a slow pace despite the positive prospect of hematite having the suitable bandgap and being low cost, and the limiting factor has been the intrinsic physical and chemical properties of this material. The hetero-nanostructures of the present disclosure tackle these deficiencies by combining a highly conductive interfacing material with a photoactive Fe₂O₃ coating. The highly conductive interfacing material acts as a structural support for the uniform thin Fe₂O₃ coating, and as a dedicated charge transport pathway with high surface area. The interfacing material provides superior conductance, thus carrying away collected electrons once illuminated, but also improves (at least maintains) the surface-to-volume ratio for good light absorption and chemical reactions. The interfacing material is in the nanoscale range (for high surface area), is electrically connected (for efficient charge transport), and is intrinsically conductive. The interfacing material absorbs light to a limited extent, leaving most of the optical energy to the hematite shell. Interfacing materials include, but are not limited to, vertically-aligned metal nanowires, vertically-aligned transparent conductive oxides (tin-doped indium oxide (ITO) nanowires and aluminum doped zinc oxide (AZO) nanowires and nanotubes), unaligned metal nanowires, unaligned transparent conductive oxides, nanonets (NNs), porous carbon, like those used in Li ion battery anodes, heavily doped Si nanostructures, silicides of titanium (TiSi₂), cobalt (CoSi₂), and nickel (NiSi), and sulfides, such as copper sulfide (Cu₂S)

In an embodiment, the present disclosure relates to the combination of photoactive ultrathin hematite with highly conductive complex titanium disilicide nanonets to yield Fe₂O₃/TiSi₂ hetero-nanostructures of the present disclosure. Atomic layer deposition is used to synthesize ultrathin hematite with excellent control over film composition and uniformity. The ultrathin hematite is photoactive, even with film thickness less than 20 nm. The titanium disilicide nanonets, with high surface area and excellent conductivity, enhance the light absorption and charge transfer. The Fe₂O₃/TiSi₂ hetero-nanostructures of the present disclosure have great potential to significantly advance the efficiency of solar water splitting by improving the hematite and nanonets at the same time.

The lowest resistivity of Si one can achieve is around 1 mΩ·cm, about 10 times higher than that of TiSi₂. The interfacing materials to be used have electron energy levels (Fermi level) similar to those of hematite. In an embodiment, the interfacing materials to be used do not have a significant mismatch with hematite in terms of electron energy levels. Otherwise, a significant barrier would be created, thereby lowering the efficiency. In an embodiment, the interfacing material is TiSi₂. The hematite shell is able to absorb solar light, excite and separate electrons and transfer the separated charges (electrons or holes) to the solution to create H₂ (or O₂).

In an embodiment, the hetero-nanostructures of the present disclosure are useful for high efficiency solar energy conversion. In an embodiment, the hetero-nanostructures of the present disclosure are used as photoelectrochemical cells for H₂ production from H₂O splitting by harvesting solar energy. In an embodiment, the hetero-nanostructures of the present disclosure are used as photovoltaic solar cells. In an embodiment, the hetero-nanostructures of the present disclosure are used as photocatalyst for pollutants treatments. In an embodiment, the hetero-nanostructures of the present disclosure are used to enhance the efficiency of water splitting to generate hydrogen fuel. In an embodiment, the hetero-nanostructures of the present disclosure are used as a battery electrode. In an embodiment, the hetero-nanostructures of the present disclosure are used as an anode material for a Li-ion battery.

Silicides are highly conductive materials formed by alloying silicon with selected metals. Titanium silicide (TiSi₂) is an excellent electronic material and is one of the most conductive silicides (resistivity of about 10 micro-ohm-centimeters (μΩ·cm)). TiSi₂ has recently been demonstrated to behave as a good photocatalyst to split water by absorbing visible lights, a promising approach toward solar H₂ as clean energy carriers. Better charge transport offered by complex structures of nanometer-scaled TiSi₂ is desirable for nanoelectronics and solar energy harvesting. Capabilities to chemically synthesize TiSi₂ are therefore appealing. Synthetic conditions required by the two key features of complex nanostructures, low dimensionality and complexity, however, seem to contradict each other. Growth of one-dimensional (1D) features involves promoting additions of atoms or molecules in one direction while constraining those in all other directions, which is often achieved either by surface passivation to increase energies of sidewall deposition (such as solution phase synthesis) or introduction of impurity to lower energies of deposition for the selected directions (most notably the vapor-liquid-solid mechanism). Complex crystal structures, on the other hand, require controlled growth in more than one direction. The challenge in making two-dimensional (2D) complex nanostructures is even greater as it demands more stringent controls over the complexity to limit the overall structure within two dimensions. The successful chemical syntheses of complex nanostructures have been mainly limited to three-dimensional (3D) ones. In principle, 2D complex nanostructures are less likely to grow for crystals with high symmetries, e.g. cubic, since various equivalent directions tend to yield a 3D complex structure; or that with low symmetries, e.g. triclinic, monoclinic or trigonal, each crystal plane of which is so different that simultaneous growths for complexity are prohibitively difficult.

In an embodiment, a chemical vapor deposition (CVD) system is used for the fabrication of complex two-dimensional (2D) conductive silicide nanostructures of the presently disclosed embodiments. An example of a suitable system for the fabrication 2D conductive silicide nanostructures of the present disclosure is disclosed in co-pending U.S. application Ser. No. 12/546,804, entitled “Methods of Fabricating Complex Two-Dimensional Conductive Silicides,” which is incorporated herein by reference in its entirety for the teachings therein.

Generally, various growth parameters, such as pressure, precursor ratios, temperatures and carrier gases, results in various silicide nano structures. In an embodiment, the 2D conductive silicide nanostructures are titanium silicide (TiSi₂) nanonets. It should be noted that other 2D conductive silicide nanostructures can be fabricated using the methods of the presently disclosed embodiments, including, but not limited to, nickel silicide, iron silicide, platinum silicide, chromium silicide, cobalt silicide, molybdenum silicide and tantalum silicide. Methods of fabricating 2D conductive silicides include performing chemical vapor deposition, wherein one or more gas or liquid precursor materials carried by a carrier gas stream react to form a nanostructure having a mesh-like appearance and including a plurality of connected and spaced-apart nanobeams linked together at an about 90° angle.

A CVD system used for the fabrication of complex two-dimensional (2D) conductive silicide nanostructures of the presently disclosed embodiments can have, for example, automatic flow and pressure controls. Flow of a precursor gas and a carrier gas are controlled by mass flow controllers, and fed to a growth (reaction) chamber at precise flow rates. The flow rate for the precursor gas is between about 20 standard cubic centimeters per minute (sccm) and about 100 sccm. In an embodiment, the flow rate for the precursor gas is about 50 sccm. In an embodiment, the precursor gas is present at a concentration ranging from about 1.3×10⁻⁶ mole/L to about 4.2×10⁻⁶ mole/L. In an embodiment, the precursor gas is present at a concentration of about 2.8±1×10⁻⁶ mole/L. The flow rate for the carrier gas is between about 80 standard cubic centimeters per minute (sccm) and about 130 sccm. In an embodiment, the flow rate for the carrier gas is about 100 sccm. A precursor liquid is stored in a cylinder and released to the carrier gas mass flow controller through a metered needle control valve. The flow rate for the precursor liquid is between about 1.2 sccm and 5 sccm. In an embodiment, the flow rate for the precursor liquid is about 2.5 sccm. In an embodiment, the precursor liquid is present at a concentration ranging from about 6.8×10⁻⁷ mole/L to about 3.2×10⁻⁶ mole/L. In an embodiment, the flow rate for the precursor liquid is present at a concentration of about 1.1±0.2×10⁻⁶ mole/L. All precursors are mixed in a pre-mixing chamber prior to entering the reaction chamber. The pressure in the reaction chamber is automatically controlled and maintained approximately constant by the combination of a pressure transducer and a throttle valve. In an embodiment, the system is kept at a constant pressure of about 5 Tarr during growth. The variation of the pressure during a typical growth is within 1% of a set point. All precursors are kept at room temperature before being introduced into the reaction chamber. A typical reaction lasts from about five minutes up to about twenty minutes. The reaction chamber is heated by a horizontal tubular furnace to temperature ranging from about 650° C. to about 685° C. In an embodiment, the reaction chamber is heated to a temperature of about 675° C.

In an embodiment, the precursor liquid is a titanium containing chemical. Examples of titanium containing chemicals include, but are not limited to, titanium beams from high temperature (or electromagnetically excited) metal targets, titanium tetrachloride (TiCl₄), and titanium-containing organomettalic compounds. In an embodiment, the precursor gas is a silicon containing chemical. Examples of silicon containing chemicals include, but are not limited to, silane (SiH₄), silicon tetrachloride (SiCl₄), disilane (Si₂H₆), other silanes, and silicon beams by evaporation. In an embodiment, the carrier gas is selected from the group consisting of hydrogen (H), hydrochloric acid (HCl), hydrogen fluoride (HF), chlorine (Cl₂), fluorine (F₂), and an inert gas.

2D conductive TiSi₂ nanostructures disclosed herein are spontaneously fabricated in the CVD system when the precursors react and/or decompose on a substrate in the growth chamber. This spontaneous fabrication occurs via a seedless growth, i.e., no growth seeds are necessary for the growth of the 2D conductive TiSi₂ nanostructures. Therefore, impurities are not introduced into the resulting nanostructures. The fabrication method is simple, no complicated pre-treatments are necessary for the receiving substrates. The growth is not sensitive to surfaces (i.e., not substrate dependent). No inert chemical carriers are involved (the carrier gas also participates the reactions). 2D conductive TiSi₂ nanostructures disclosed herein exhibit high conductivity and suitably high surface area.

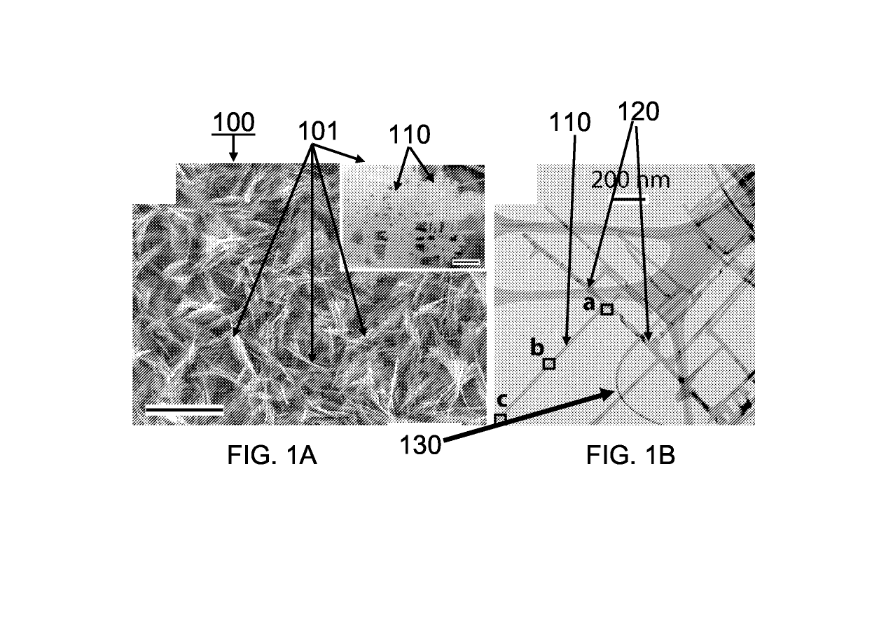

FIG. 1A and FIG. 1B show electron micrographs of a complex 2D conductive TiSi₂ nanostructure 100 of the present disclosure fabricated as described above. FIG. 1A is a scanning electron micrograph (SEM) showing the complex nanostructure 100. The nanostructure 100 is composed of a plurality of 2D nanonet sheets (NNs) 101. At relatively low magnifications, the nanostructure 100 packs to resemble tree leaves, except that each NN 101 is composed of nanobelts 110, as revealed by the close-up inset. (Scale bars: 5 μm in main frame, and 100 nm in the inset). The nanostructure 100 is better visualized under transmission electron microscope (TEM), as shown in FIG. 1B. Within each of the NNs 101 are approximately 25 nm wide and approximately 15 nm thick nanobelts 110, all linked together by single crystalline junctions 120 with about 90° angles. In an embodiment, the nanobelts 110 are substantially perpendicular to each other. One of the nanobelts 130 is twisted at the bottom of the picture, demonstrating belt-like characteristics.

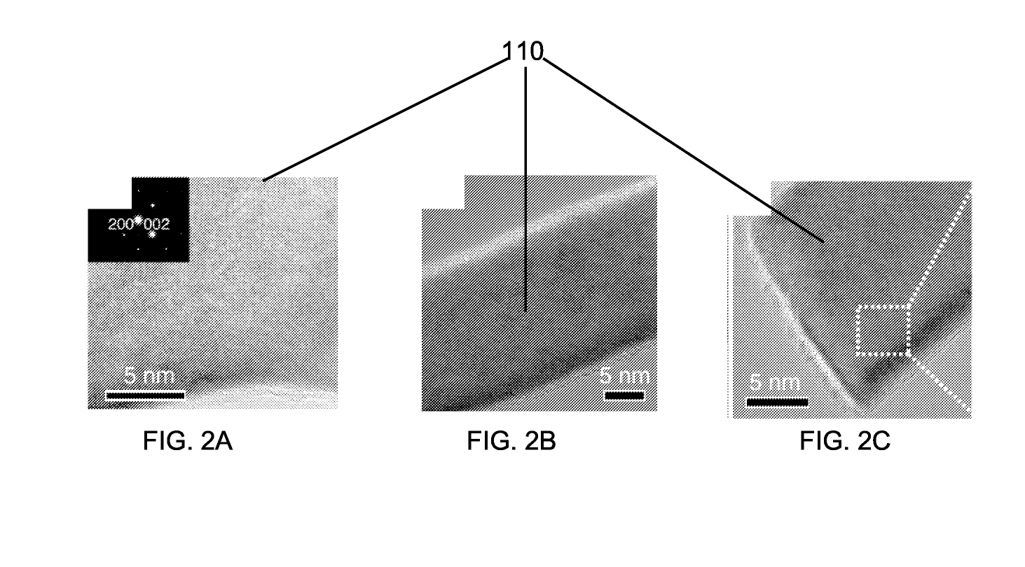

High resolution transmission electron microscopy (HRTEM) images and electron diffraction (ED) patterns of different regions of the nanobelt 110 from FIG. 1B, reveal that the entire nanobelt 110 structure is single crystalline, including the 90° joints (FIG. 2A), the middle (FIG. 2B) and the ends (FIG. 2C). The ends of the nanobelts 110, within any NN 101, are free of impurities (FIG. 2C). The nanobelts 110 are nanobeams based on two main observations: loose ends often bend on TEM supporting films, showing characteristics of nanobeams (see 130 in FIG. 1B), and the thickness of the NN (approximately 15 nm) is thinner than the width of the NN (approximately 25 nm).

Complex core/shell hetero-nanostructures of the present disclosure, which combine highly conductive two-dimensional (2D) complex nanonets with a photoactive coating, offer outstanding charge transport among branches that are linked by single crystalline junctions. In an embodiment, the hetero-nanostructures of the present disclosure combine highly conductive complex TiSi₂ nanonets (NNs) with photoactive Fe₂O₃ coating (as termed herein, Fe₂O₃/TiSi₂ hetero-nanostructures). In an embodiment, fabrication of complex Fe₂O₃/TiSi₂ hetero-nanostructures of the present disclosure includes the growth of two-dimensional (2D) TiSi₂ NNs by reacting TiCl₄ and SiH₄ in H₂ using CVD, as described above. In brief, 50 sccm SiH₄ (10% in He), 2 sccm Cl₄ and 100 sccm H₂ are co-fed into the growth chamber simultaneously. The reaction typically takes place at 675° C. for about 15 minutes. The system is maintained at 5 Torr through out the growth, and growth occurs without growth seeds. Once produced, the SiH₄ feeding is stopped while the TiCl₄ and H₂ flow are continued at 675° C. for about 5 minutes. Ti foils coated with 100 nm Pt film was used to collect the products. This treatment results in a thin Ti passivation layer that is important to the properties. The CVD system used to grow the highly conductive complex TiSi₂ nanonets of the present disclosure have automatic pressure and flow controls.

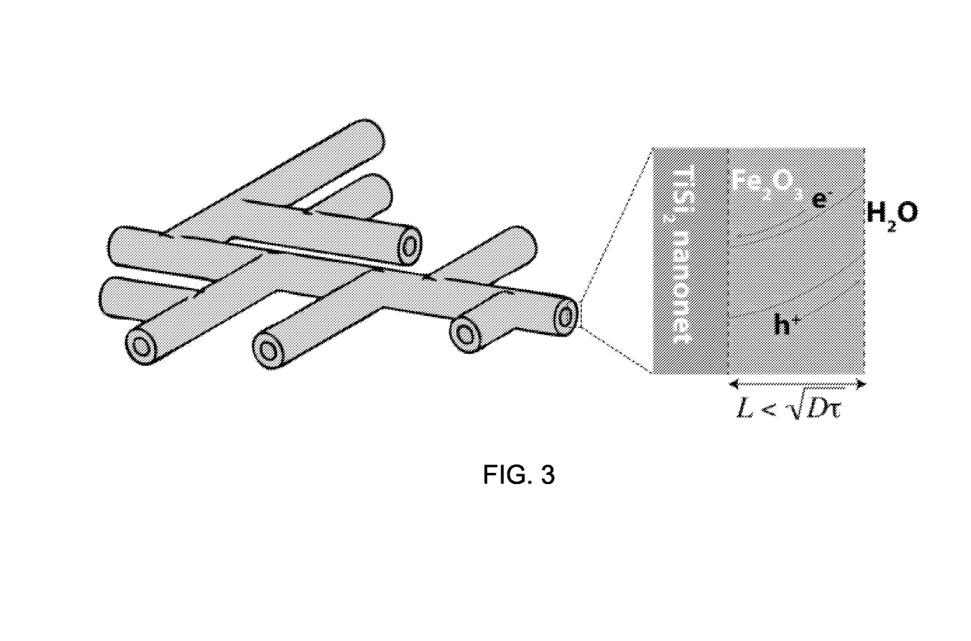

In an embodiment, as illustrated in FIG. 3, when a thin Fe₂O₃ coating is interfaced with a TiSi₂ nanonet, the longest distance from anywhere in the semiconductor to a location where charges can be scavenged (by H₂O oxidation in the solution) or transported (by TiSi₂) is shorter than the charge diffusion distance, permitting effective charge collection. To actualize the full potential of this design, high-quality hematite was synthesized that is thin and conforms to the TiSi₂ nanonet uniformly using an atomic layer deposition (ALD) technique. Before the hematite deposition, the TiSi₂ nanonets are annealed in forming gas (5% of hydrogen in nitrogen). In an embodiment, the TiSi₂ nanonets are annealed in forming gas (5% of hydrogen in nitrogen) at a temperature ranging from about 500° C. to about 900° C. for about 30 seconds to about 30 minutes. In an embodiment, the TiSi₂ nanonets are annealed in forming gas (5% of hydrogen in nitrogen) at a temperature of about 600° C. for about 1 minute. In an embodiment, such annealing passivates and reduces the surface states of TiSi₂ nanonets, which may facilitate charge transfer from iron oxide to TiSi₂ nanonets.

After the annealing step, the hematite shell is synthesized on the conductive nanonets. In an embodiment, the iron oxide coating is synthesized by an ALD process using iron tert-butoxide (heated to about 140° C.) and water (at about 25° C.) as iron and oxygen precursor, respectively. In an embodiment, iron tert-butoxide is synthesized as follows: 6.3 g sodium tert-butoxide (Sigma) and 3.2 g iron chloride (anhydrous, Sigma) are mixed in 240 mL tetrahydrofuran (anhydrous, Sigma). The mixture is heated to 60° C. by water bath for 5 h. Afterward, the solvent is removed by distillation at 80° C. and then transferred to a precursor bubbler for the ALD growth. During the preparation, Ar is flowing to keep the reaction under inert gas environment. The ALD growth can be carried out at 180° C. with 10 sccm N₂ flowing. TiSi₂ nanonets and FTO substrate are used as substrate. In an embodiment, a stopvale mode procedure for the growth of iron oxide is employed to ensure the reaction between iron precursor and water. In an embodiment, the stopvalve mode procedure is as follows:

| | | Fe₂(O^{t}Bu)₆ | | Pump |
|---|---|---|---|---|
| Designation | Duration (s) | valve | H₂O valve | valve |
| Fe₂(O^{t}Bu)₆ pulse | 5 | Open | Closed | Closed |
| Fe₂(O^{t}Bu)₆ exposure | 15 | Closed | Closed | Closed |
| Purge | 10 | Closed | Closed | Open |
| H₂O pulse | 0.05 | Closed | Open | Closed |
| H₂O exposure | 15 | Closed | Closed | Closed |
| Purge | 10 | Closed | Closed | Open |

The stopvalve mode procedure described above yielded a much higher growth rate (0.6 Å/cycle) of iron oxide compared with what has been disclosed in the literature (the highest rate previously reported was 0.26 Å/cycle). Typically, a 400-cycle iron oxide growth produced a 25 nm thick film. After growth, the samples were postannealed in O₂ for 15 min at 500° C. to improve crystallinity.

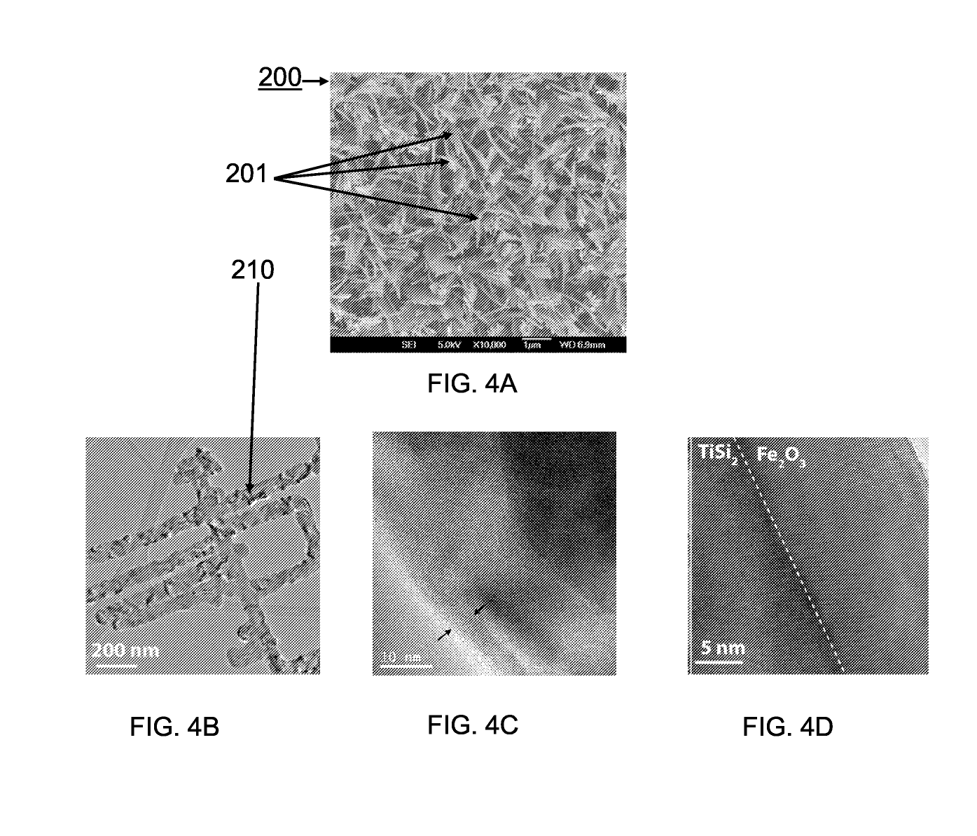

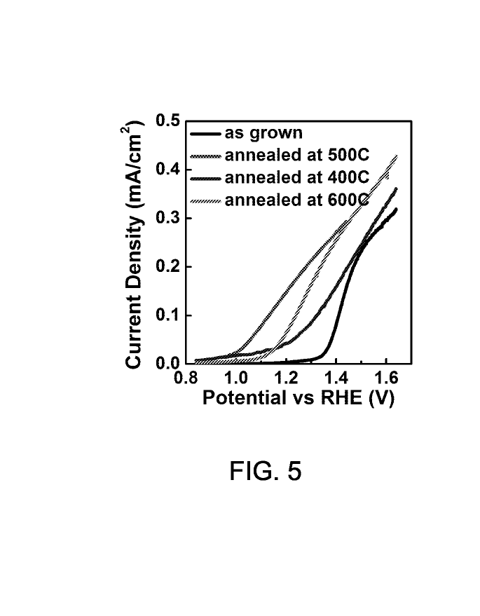

A Fe₂O₃/TiSi₂ hetero-nanostructure of the present disclosure, produced using methods described above, was examined using a Scanning Electron Microscope and a Transmission Electron Microscope. FIG. 4A is a SEM of a conductive Fe₂O₃/TiSi₂ hetero-nanostructure 200 of the present disclosure fabricated as described above. The hetero-nanostructure 200 is composed of a plurality of 2D nanonet sheets (NNs) 201 composed of a uniform thin layer of iron oxide interfaced with TiSi₂. The hetero-nanostructure 200 packs to resemble tree leaves, except that each NN 201 is composed of nanobelts 210. The hetero-nanostructure 200 is better visualized under transmission electron microscope (TEM), as shown in FIG. 4B. Within each of the NNs 201 are approximately 25 nm wide and approximately 15 nm thick nanobelts 210, all linked together by single crystalline junctions 120 with about 90° angles. In an embodiment, the nanobelts 210 are substantially perpendicular to each other. The Fe₂O₃ coating around the TiSi₂ nanonet is uniform (FIG. 4B) and the interface between Fe₂O₃ and TiSi₂ is defect free (FIG. 4D). Films thinner than 10 nm, as indicated by the black arrows in FIG. 4C, are still photoactive. FIG. 5 shows I-V curves as a function of annealing temperatures. In general, samples with curves to the right are less active. The black curve in FIG. 5 is the material without the annealing step. There is no measureable current at 1.23 V (the reversible O₂ generation potential). Current was still measured at higher potentials because electrolysis still happens. It is different from photo water splitting though because the energy comes from the electricity, not the light.

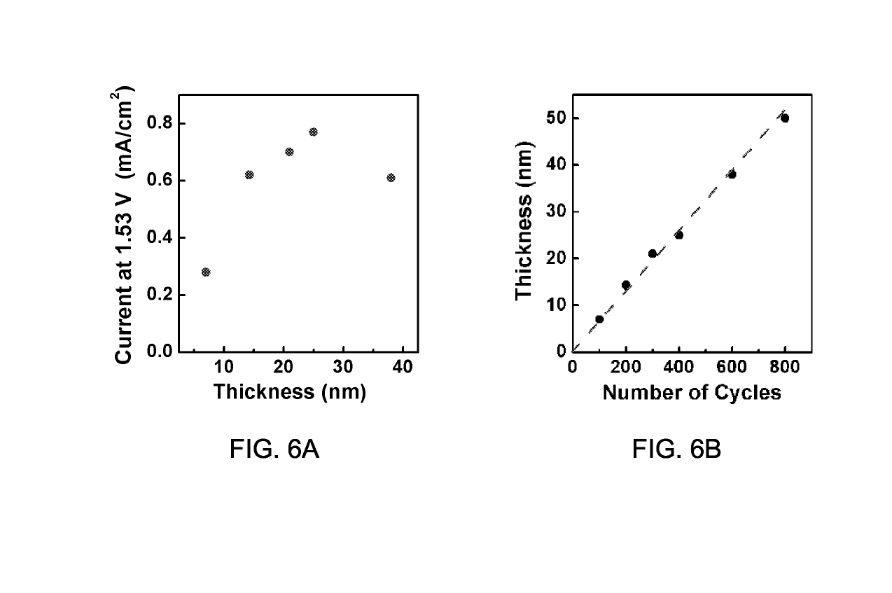

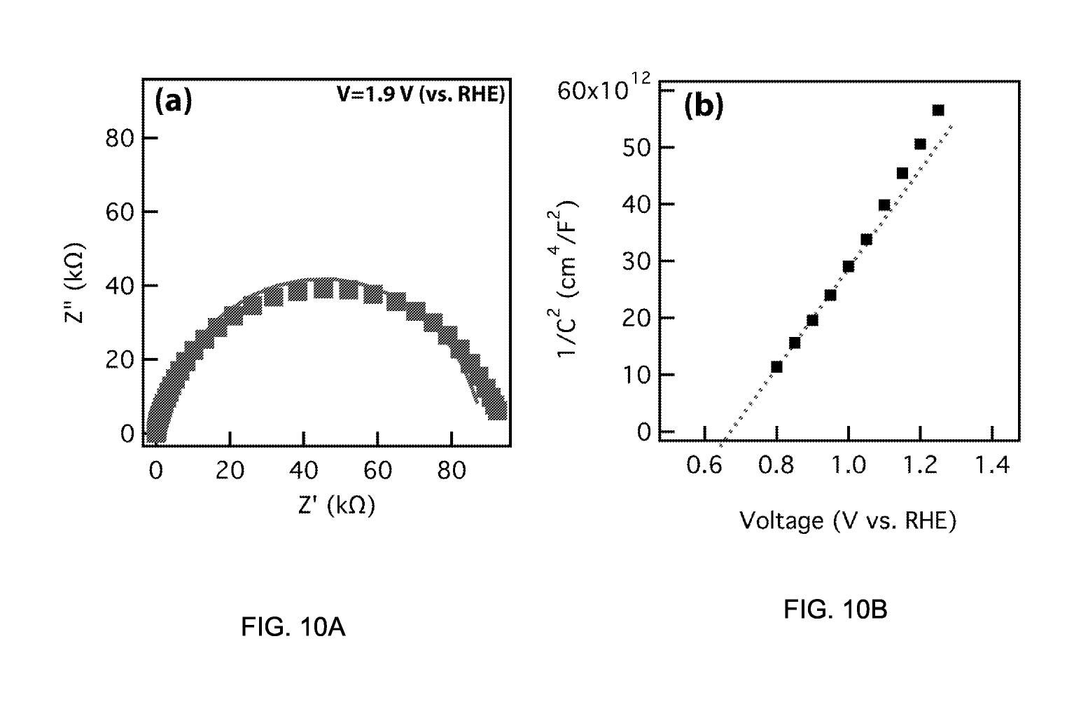

Previously, it has generally been accepted that iron oxide is not photoactive when thinner than 50 nm. Such a property will greatly limit its applications for water splitting. In an embodiment, the hetero-nanostructures of the present disclosure, having an iron oxide shell of less than 50 nm, are photoactive, as evidenced in the plots shown in FIG. 6A. FIG. 6A shows that iron oxide was still photoactive for films as thin as 7 nm. This result demonstrates the ability to control the synthesis of iron oxide and the excellent quality of the resulting film. The photocurrent drops rapidly with the increase of iron oxide thickness beyond 40 nm. It is so because of poor charge collection from thick films. In an embodiment, the thickness of the iron oxide for this specific application ranges from about 7 nm to about 40 nm. In an embodiment, the thickness of the iron oxide for this specific application ranges from about 25 nm to about 30 nm. The growth technique offers several distinct advantages. For example, the disclosed method produces an extremely uniform coating that conforms to the receiving substrate, whether that substrate is planar or a nanostructure with complex features. This feature will allow for charge transfer from Fe₂O₃ to TiSi₂ without significant impedance, which is confirmed by electrochemical impedance spectroscopy (EIS) measurements (FIG. 10A and FIG. 10B, the details of which will be discussed later). The post growth annealing (post-annealing) of iron oxide is important to achieve the desired photoactivities. For example, in an embodiment, oxygen annealing at 500° C., with 20° C./min ramping rate for about 15 minutes, helps to crystallize the iron oxide. FIG. 6B is a chart showing the thickness of iron oxide versus the number of ALD growth cycles. The red dashed line is a linear fit to the discrete data points. The average growth rate is approximately 0.62 Å/cycle.

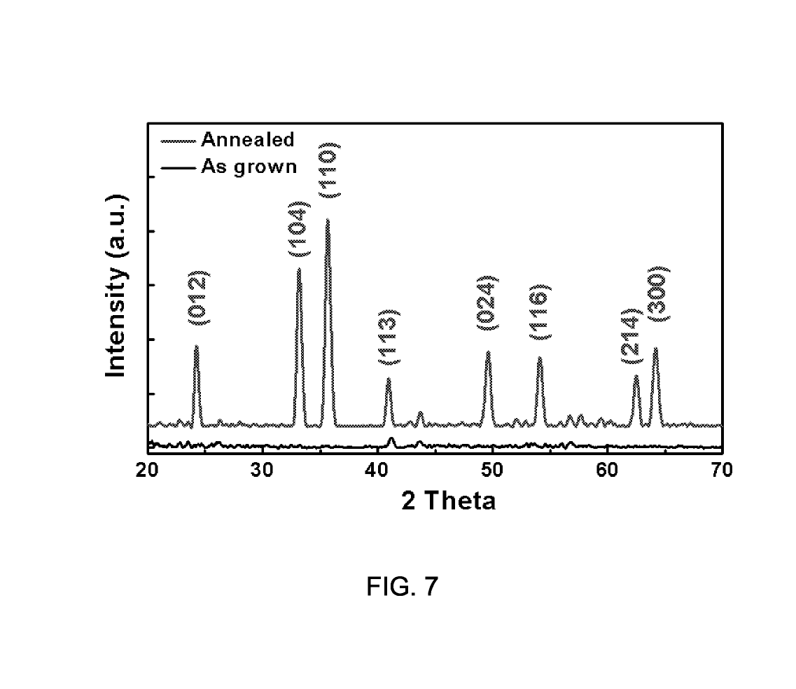

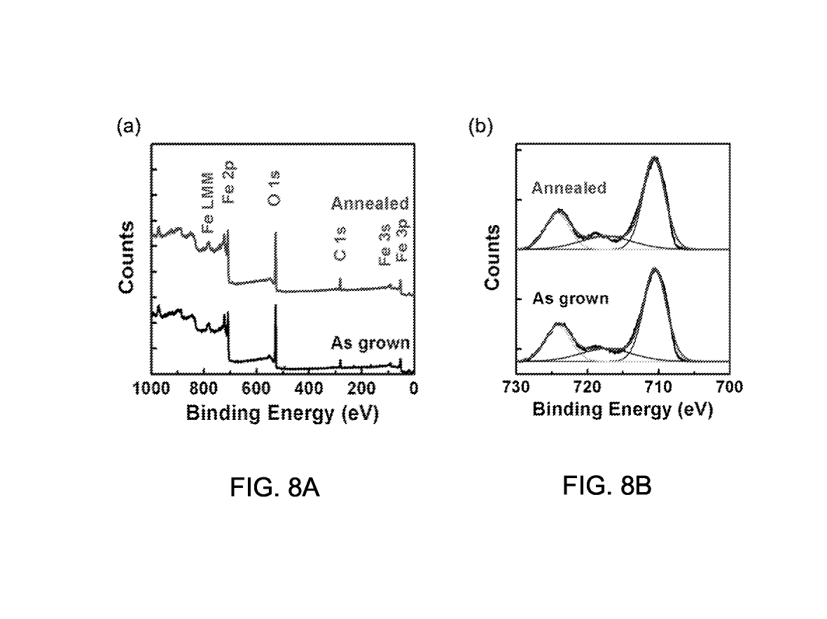

An X-ray Diffractrometer (XRD) and an X-ray photoelectron Spectrometer (XPS) was used for the crystal structure study and elemental analysis, respectively. FIG. 7 shows an XRD plot of iron oxide on TiSi₂ with (red trace) and without annealing (black trace). The crystal structure was identified to be hematite. As-grown Fe₂O₃ is of poor crystallinity. FIG. 8A and FIG. 8B show XPS plots of iron oxide before and after annealing. FIG. 8A is a survey scan of XPS data with peak assignments labeled. FIG. 8B is a fine scan of the Fe 2p region. No change of oxidation state was observed before and after annealing. The binding energies for Fe 2p_{3/2} and Fe 2p_{1/2} are 710.9 and 724.3 eV, respectively, in excellent agreement with literature reports on α-Fe₂O₃.

Once prepared, the Fe₂O₃/TiSi₂ hetero-nanostructures (Fe₂O₃ thickness: 25 nm) were then made into electrodes. Ti foils coated with Fe₂O₃/TiSi₂ hetero-nanostructures were connected to a copper wire using conductive silver epoxy (SPI supplies). Afterwards, the entire substrate except the front side with the hetero-nanostructures was covered by non-conductive Loctite® Hysol® epoxy. A UV-Ozone (Jelight Company Inc.) exposure (3 min) was performed to this region immediately before the PEC measurements. PEC measurements were conducted using a CHI 608C Potentiostat/Galvanostat in a three-electrode configuration, with Fe₂O₃/TiSi₂ as working electrode, a Pt mesh as the counter electrode, and a Hg/HgO in 1M NaOH as the reference electrode. The electrolyte was 1 M NaOH solution, the pH of which was 13.60 as verified by an Orion 4-Star pH meter (Thermo Scientific). The measured voltage was converted into the potential vs. reversible hydrogen electrode (RHE). The current flowing into the photoanode was defined as positive. As a precaution to exclude any influence of dissolved gases such as O₂, the solution was bubbled with N₂ for 20 min before a measurement. In a typical experiment, the potential was linearly swept from 0.8 V to 1.7 V vs. RHE at a scan rate of 10 mV/s. Other sweeping ranges, directions and rates were also tested. The light source was an AM 1.5 solar simulator (Oriel, mode 96000) with the illumination intensity adjusted to 100 mW/cm².

The absorbance was calculated from the formula A=−log(T+R),⁴ where A is the absorbance, T is the total transmittance, and R is the total reflectance. T and R was measured using integrating sphere (Sphere Optics) coupled with a spectrometer (Ocean Optics USB 4000). Iron oxide on quartz was used for this measurement to eliminate the influence of the FTO coating. The incident photon-to-charge conversion efficiencies (IPCE) were measured using a solar simulator (Oriel, mode 96000) coupled with a monochromator (Oriel Cornerstone 260). The intensity of the monochromatic light was measured by a calibrated Si detector (Oriel, Model 71640). The working electrode was biased at 1.53 V (vs. RHE) using the same configuration as described above. Absorbed photon-to-current conversion efficiencies (APCE) were calculated for iron oxide on FTO substrate using following equation:

$$APCE = \frac{IPCE}{1 - {10}^{- A}}$$

where A is the absorbance as described above.

Electrochemical impedance spectroscopy measurement was performed by a three-electrode configuration using CHI 604C, as described above. A sinusoidal voltage perturbation, with amplitude of 5 mV and frequencies ranging from 100,000 to 1 Hz was superimposed on the bias voltage. The impedance was measured at bias voltages from 1.1 to 2.1 V vs RHE. All EIS measurements were performed in dark. The Nyquist plot obtained from EIS measurement was simulated using the following equivalent circuit and the CHI 604C software:

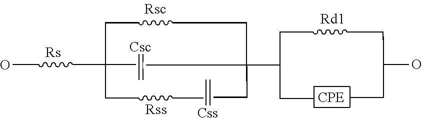

Equivalent circuit used to simulate the Nyquist plot measured by EIS. Rₛ is the series resistance. R_{sc} and C_{sc} represent the charge transfer resistance and capacitance of space charge region, respectively. Rₛₛ and Cₛₛ represent the resistance and capacitance of surface states, respectively. R_{dl} and CPE represent the resistance and capacitance of double layer, respectively.

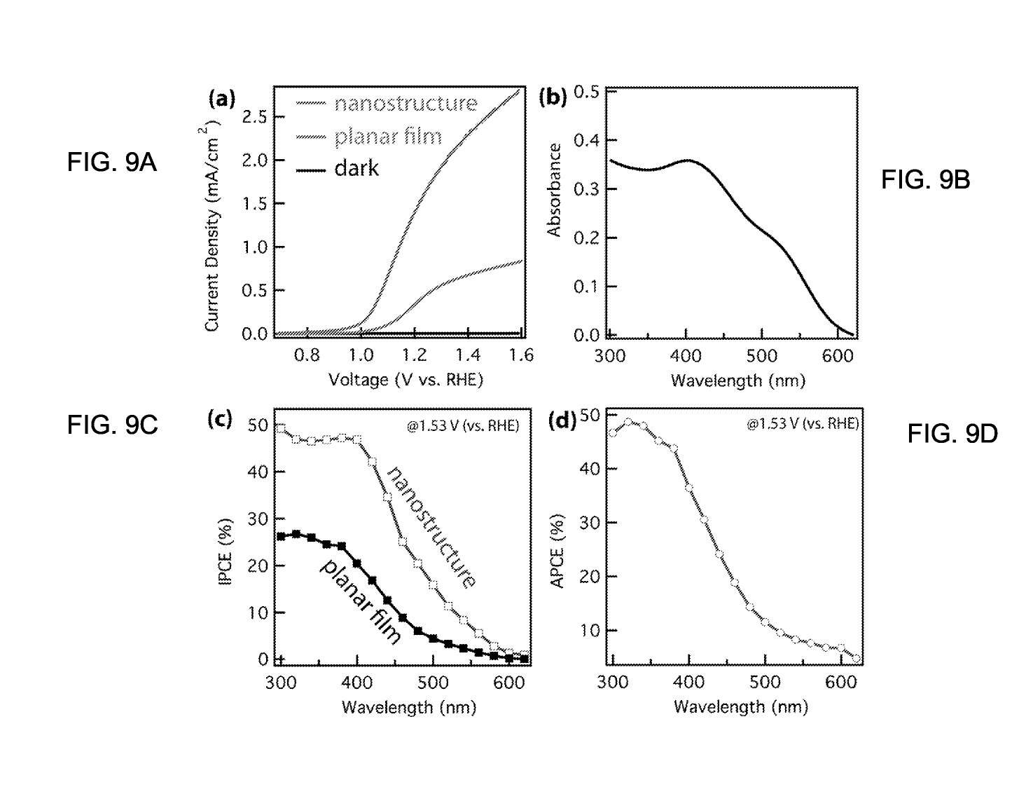

The relatively low photocurrent of intrinsic iron oxide measured on planar FTO substrate is in part due to the poor light absorption by the thin film on FTO. To estimate the maximum photocurrent an electrode can deliver under solar AM 1.5 illumination, it was assumed that all photons are absorbed by the electrode and the absorbed photon-to-charge conversion efficiencies (APCE) were calculated. By integrating the APCE spectrum over the photon flux obtained from standard AM 1.5 solar spectrum, the maximum photocurrent expected from intrinsic iron oxide was obtained and found to be approximately 2 mA/cm² at 1.53V vs RHE. FIG. 9A shows characteristic PEC data of a Fe₂O₃/TiSi₂ hetero-nanostructure of the present disclosure and planar hematite film. In dark, no measureable current was observed up to 1.60 V, indicating that a band bending is formed between Fe₂O₃ and the electrolyte, and the resulting built-in field prevents charge transfer from the solution to the semiconductor (or vise versa). In contrast, a large current was measured when the electrode was illuminated (2.7 mA/cm² at 1.53 V; 1.6 mA/cm² at 1.23 V). These measurements were performed on Fe₂O₃ without any co-catalysts. This result supports that the hetero-nanostructure design of the present disclosure is an alternative to doping to improve charge collection. Further increase of the photocurrent should be possible by, for example, the usage of co-catalyst to lower the onset potential (presently at ˜0.90 V).

The incident photon-to-charge conversion efficiencies (IPCE) of the Fe₂O₃/TiSi₂ hetero-nanostructure was measured as a function of wavelength, and the data are plotted in FIG. 9C. The plots in FIG. 9C show the difference between the performance of the hetero-nanostructures of the present disclosure and that of the planar films, the former being nearly twice as high as the latter. The introduction of a highly conductive component increases the IPCE. The highest IPCE (46% at 400 nm) is equal to or better than those in the existing reports. That it is significantly lower than those of TiO₂ or WO₃ (which are typically >80%) suggests there is plenty of room for improvement, either in light absorption or in charge collection or both. To understand which factor is more important, the adsorbed photon-to-charge conversion efficiencies (APCE) of planar Fe₂O₃ (25 nm) grown on fluorinated tin oxide (FTO)-coated glass were examined. As shown in FIG. 9D, the APCE of the Fe₂O₃ thin film is on the same level as the the IPCE of the Fe₂O₃/TiSi₂ hetero-nanostructure of the present disclosure. The slight deviation may be a result of the measurement artifact due to the thinness of the film. Lower APCE was measured on thicker Fe₂O₃ films, presumably because of the poor charge collection. The hetero-nanostructure design exhibits the highest IPCE measured on intrinsic Fe₂O₃.

The ability to prepare ultra-thin crystalline Fe₂O₃ allows for the measurement of the internal quantum efficiencies without being confounded by poor charge collection. The results reveal that even when only the absorbed photons are considered, a relatively low (<50%) quantum efficiency is measured, and the efficiency is especially low in the long wavelength range where the excited electrons are of lower energy (e.g., ˜16% at 500 nm), as shown in FIG. 9B. This finding is in line with current literature reports that the quantum yield for converting photons with energies close to Fe₂O₃ band edge is low.

Because a low-impedance across the interface between Fe₂O₃ and TiSi₂ is desired in the realization of the nanonet-based design, a study was carried out on this interface using EIS in dark under steady-state conditions. A potential (varying from 1.1 to 2.1 V) was applied and the system was allowed to equilibrate for 5 min. Afterwards, an alternating current (AC) perturbation (frequencies changing from 100,000 to 1 Hz) to the applied potential with a magnitude of 5 mV was exerted, and the impedance change in response to the perturbation was measured. A typical set of data (at 1.9V) is plotted in FIG. 10A in the form of a Nyquist plot.

An equivalent electrical circuit was then employed to analyze the data. This technique allows one to single out two important elements of the hetero-nanostructures of the present disclosure in a quantitative fashion: the series resistance including that between TiSi₂ and Fe₂O₃, as well as the capacitance of the depletion region within Fe₂O₃, as shown in FIG. 10B. The variation of the measured series resistance (˜8 Ω) as a function of the applied potential is minimal, suggesting that charge transfer from Fe₂O₃ to the TiSi₂ nanonet and then to the charge collector is efficient. The measured depletion region capacitance, on the other hand, decreases monotonically as the potential is increased following what is described by the Mott-Schottky (M-S) relation, fitting to which (between 0.8 and 1.1. V vs. RHE) produces two important properties of the Fe₂O₃: the flatband potential (V_{fb}, 0.67 V) and the carrier concentration (7.110¹⁵/cm³). Alternatively, the M-S plot could be obtained by directly measuring the capacitance of the system. However, due to the complexities of the semiconductor/electrolyte interfaces this approach failed to yield meaningful V_{fb} and carrier concentration values. The measured V_{fb} falls in the relevant range that has been reported by the literature but higher than V_{fb} of Fe₂O₃ produced by Sivula and Gratzel et al. The difference may be a result of the low carrier concentration, which also manifests the purity of the ALD-produced Fe₂O₃ coating.

In an embodiment, to improve the collection of charges generated by long wavelength photons close to the bandgap edge so as to result in the reduction in charge recombination, doped iron oxide may be used as the photoactive shell in the hetero-nanostructures of the present disclosure. Doping has been studied to improve the photoelectrochemical performance of iron oxide photoanode by improving the charge transfer or by reducing charge recombination. To further improve the performance of iron oxide, the doping can be realized in a hetero-nanostructure of the present disclosure. Atomic layer deposition, which is used to deposit the iron oxide film, has the advantage of tuning the film composition with a high degree of control. Si, Ti, or Sn which are the most effective dopants, could be used. For example, tetrakis (dimethylamino)silane or vinyl-trimethoxysilane can be used as the silicon precursor. Titanium tetrachloride or titanium isopropoxide can be used as the titanium precursor. Tin tetrachloride could be used as the tin precursor. Dopant is incorporated during the ALD growth of iron oxide with tunable concentration. The dopant concentration could be tuned by adjusting the ratio of pulse cycles of iron and dopant precursor.

In an embodiment, to improve the collection of charges generated by long wavelength photons close to the bandgap edge so as to result in the reduction in charge recombination, co-catalysts may be added to iron oxide and the co-catalysts/iron oxide may be used as the photoactive shell in the hetero-nanostructures of the present disclosure. Oxygen evolving catalyst has been studied to improve the performance of iron oxide photoanode by reducing the oxygen generation overpotential. Various catalysts such as iridium oxide nanoparticles, cobalt-phosphate, or brudvig-crabtree catalyst can be used to improve the performance. These catalysts can be easily deposited via different methods on the electrodes. For example, the iridium oxide nanoparticles can be synthesized by a solution-based approach and then deposited on the electrode by a simple electrophoresis method. Cobalt-phosphate catalyst can be deposited via electrodeposition in a solution containing cobalt nitrate and potassium phosphate. A simple method via thermal treatment can be employed to deposit Mn-based catalyst derived from brudvig-crabtree catalyst. It is believed that by combining these various oxygen evolving catalysts with a hematite hetero-nanostructure of the present disclosure, the efficiency can be further improved.

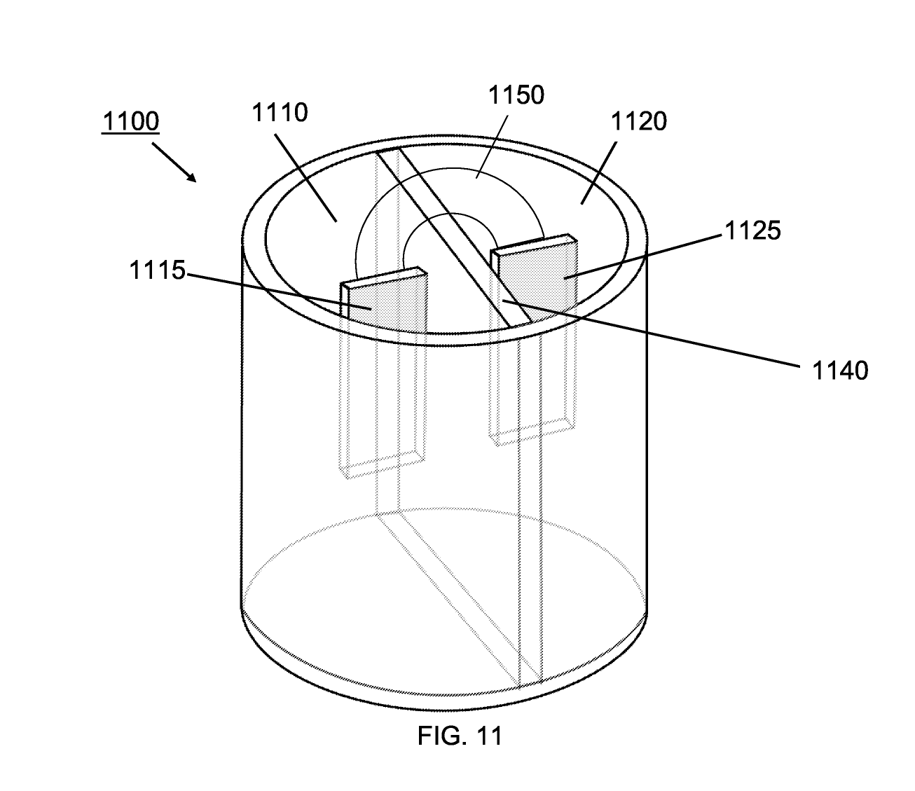

FIG. 11 shows an exemplary illustration of a device 1100 of the present disclosure for use in water splitting. The device 1100 includes two compartments, 1110 and 1120, each of which can be used for the half reactions of H₂ and O₂ generations. Solar energy is harnessed to separate charges, which then transfer to the redox pairs in the solutions to perform reactions. The appropriate energy alignment can be enabled by material choices (p-type for H₂ and n-type for O₂) and the adjustment of solution pH. Highly conductive components (such as TiSi₂) ensure efficient charge transport, thus completing the full reaction of H₂O splitting. In an embodiment, compartment 1110 is filled with an acidic solution, and compartment 1120 is filled with a basic solution. Compartments 1110 and 1120 are separated by a semi-permeable membrane 1140 that only allows ionic exchange to balance potential buildup. In an embodiment, the semi-permeable membrane 1140 is a charge-mosaic membrane (CMM). In the acidic compartment 1110, a p-type material acts to produce H₂ upon illuminations. Examples of suitable p-type materials that can be used include, nanostructures or hetero-nanostructures 1115 with p-type coating, such as, for example, Cu doped TiO₂ or hematite based hetero-nanostructures. In the basic compartment 1120, hetero-nanostructures 1125 of the present disclosure with n-type coating act to produce O₂ upon illuminations. Examples of hetero-nanostructures 1125 of the present disclosure with n-type coating that can be used include, for example, Fe₂O₃/TiSi₂ hetero-nanostructures. The supporting conductive substrates 1115 and 1125 are connected together by external contacts 1150 to ensure charge balance. In the solution, opposite charges flow through the semi-permeable membrane 1140 to annihilate each other. Both the acidic and the basic solutions should be periodically refreshed by adding more acids or bases to maintain an appropriate chemical potential difference by maintaining a preset PH difference.

In an embodiment, a hetero-nanostructure of the present disclosure includes a plurality of connected and spaced-apart nanobeams linked together at an about 90° angle, the plurality of nanobeams including a conductive silicide core having an n-type photoactive hematite shell.

In an embodiment, a device for splitting water to generate hydrogen and oxygen includes a first compartment having a two-dimensional hetero-nanostructure, the hetero-nanostructure having a plurality of connected and spaced-apart nanobeams, each nanobeam substantially perpendicular to another nanobeam, the plurality of nanobeams including an n-type photoactive hematite shell having a conductive core; and a second compartment having a p-type material, wherein the first compartment and the second compartment are separated by a semi-permeable membrane.

In an embodiment, a method of fabricating a nanonet-based hematite hetero-nanostructure includes performing chemical vapor deposition so as to fabricate a two-dimensional conductive silicide nanostructure, wherein one or more gas or liquid precursor materials carried by a first carrier gas stream react to form the nanostructure, and wherein the nanostructure has a mesh-like appearance and includes a plurality of connected and spaced-apart nanobeams linked together at an about 90° angle; annealing the nanostructure; and performing atomic layer deposition so as to deposit a conformal crystalline hematite around the nanostructure, wherein the film ranges from about 10 nm to about 40 nm, and wherein one or more gas or liquid precursor materials carried by a second carrier gas stream react to form the hematite hetero-nanostructure. In an embodiment, the method further includes annealing the hematite hetero-nanostructure. In an embodiment, the conductive silicide is a titanium silicide. In an embodiment, the one or more gas or liquid precursor materials of the chemical vapor deposition is selected from a titanium containing chemical and a silicon containing chemical. In an embodiment, the carrier gas of the chemical vapor deposition is selected from the group consisting of H, HCl, HF, Cl₂, and F₂. In an embodiment, the one or more gas or liquid precursor materials of the atomic layer deposition is selected from a titanium containing chemical such as Ti(i-PrO)₄.

All patents, patent applications, and published references cited herein are hereby incorporated by reference in their entirety. It will be appreciated that several of the above-disclosed and other features and functions, or alternatives thereof, may be desirably combined into many other different systems or applications. Various presently unforeseen or unanticipated alternatives, modifications, variations, or improvements therein may be subsequently made by those skilled in the art which are also intended to be encompassed by the following claims.

What is claimed is:

1. A hetero-nanostructure comprising a plurality of connected and spaced-apart nanobeams linked together at an about 90° angle, the plurality of nanobeams including a conductive silicide core having an n-type photoactive hematite shell.

2. The hetero-nanostructure of claim 1 wherein the conductive silicide core is a titanium silicide core.

3. The hetero-nanostructure of claim 1 wherein the n-type photoactive hematite shell includes a dopant to absorb visible light.

4. The hetero-nanostructure of claim 1 wherein the plurality of nanobeams are two-dimensional.

5. The hetero-nanostructure of claim 1 wherein the hetero-nanostructure is used as a photoelectrochemical cell.

6. The hetero-nanostructure of claim 1 wherein the hetero-nanostructure is used as a solar cell.

7. The hetero-nanostructure of claim 1 for use in producing hydrogen.

8. The hetero-nanostructure of claim 1 wherein a thickness of the n-type photoactive hematite shell ranges from about 7 nm to about 40 nm.

9. The hetero-nanostructure of claim 1 wherein a thickness of the n-type photoactive hematite shell ranges from about 25 nm to about 30 nm.

10. A device for splitting water to generate hydrogen and oxygen comprising:
a first compartment having a two-dimensional hetero-nanostructure, the two-dimensional hetero-nanostructure having a plurality of connected and spaced-apart nanobeams, each nanobeam substantially perpendicular to another nanobeam, the plurality of nanobeams including an n-type photoactive hematite shell having a conductive core; and
a second compartment having a p-type material,
wherein the first compartment and the second compartment are separated by a semi-permeable membrane.

11. The device of claim 10 wherein the conductive core is a titanium silicide core.

12. The device of claim 10 wherein the conductive core is a cuprous sulfide core.

13. The device of claim 10 wherein the n-type photoactive hematite shell includes a dopant to absorb visible light.

14. The device of claim 13 wherein the dopant includes tungsten.

15. The device of claim 10 wherein a thickness of the n-type photoactive hematite shell ranges from about 7 nm to about 40 nm.

16. The device of claim 10 wherein a thickness of the n-type photoactive hematite shell ranges from about 25 nm to about 30 nm.

17. The device of claim 10 wherein the first compartment includes a basic solution and the second compartment includes an acidic solution.

18. A method of fabricating a nanonet-based hematite hetero-nanostructure comprising:
performing chemical vapor deposition so as to fabricate a two-dimensional conductive silicide nanostructure, wherein one or more gas or liquid precursor materials carried by a first carrier gas stream react to form the nanostructure, and wherein the nanostructure has a mesh-like appearance and includes a plurality of connected and spaced-apart nanobeams linked together at an about 90° angle;
annealing the nanostructure; and
performing atomic layer deposition so as to deposit a conformal crystalline hematite around the nanostructure, wherein the film ranges from about 10 nm to about 40 nm, and wherein one or more gas or liquid precursor materials carried by a second carrier gas stream react to form the hematite hetero-nanostructure.

19. The method of claim 18 wherein the conductive silicide is a titanium silicide.

20. The method of claim 18 further comprising annealing the hematite hetero-nanostructure.
